(19) United States
(12) Patent Application Publication
(10) Pub. No.: US 2015/0139725 A1
(43) Pub. Date: May 21, 2015

(54) APPARATUS OR A METHOD

(71) Applicants: Chong Chen, Beijing (CN); Hongji Zhang, Beijing (CN)

(72) Inventors: Chong Chen, Beijing (CN); Hongji Zhang, Beijing (CN)

(73) Assignee: Nokia Corporation a corporation

(21) Appl. No.: 14/399,275

(22) PCT Filed: May 15, 2012
(86) PCT No.: PCT/CN2012/075505

§ 371 Date: Nov. 6, 2014

(51) Int. Cl. H05K 5/02

(52) U.S. Cl. CPC H05K 5/0286; H05K 5/0256
USPC 403/375; 29/592

(57) ABSTRACT

An apparatus comprising: a support comprising a planar support surface; first protrusions protruding from the planar support surface and located on the planar support surface to position a first planar component within a first area; and second protrusions protruding from the planar support surface and located on the planar support surface to position a second planar component within a second area, which overlaps the first area, wherein at least some of the second protrusions are located within the first area and are configured to retract from a first protruding configuration for positioning a second planar component into a second retracted configuration for enabling the first protrusions to position a first planar component.

### TECHNOLOGICAL FIELD

Embodiments of the present invention relate to an apparatus and a method. Some embodiments relate to an apparatus for receiving a first planar component or a different second planar component.

### BACKGROUND

Various different electronic components are provided as planar components that can be inserted and removed by a user. Examples include smart cards, subscriber identity modules and memory cards.

It would be desirable to provide an apparatus that can receive not only a first planar component but alternatively a different second planar component.

### BRIEF SUMMARY

According to various, but not necessarily all, embodiments of the invention there is provided an apparatus comprising: a support comprising a planar support surface; first protrusions protruding from the planar support surface and located on the planar support surface to position a first planar component within a first area; and second protrusions protruding from the planar support surface and located on the planar support surface to position a second planar component within a second area, which overlaps the first area, wherein at least some of the second protrusions are located within the first area and are configured to retract from a first protruding configuration for positioning a second planar component into a second retracted configuration for enabling the first protrusions to position a first planar component.

According to various, but not necessarily all, embodiments of the invention there is provided a method comprising: providing first protrusions protruding from a planar support surface and located on the planar support surface to position a first planar component within a first area; and providing second protrusions protruding from the planar support surface and located on the planar support surface to position a second smaller planar component within a second area, which overlaps the first area, wherein at least some of the second protrusions are located within the first area and are configured to retract from a first protruding configuration for positioning a second planar component into a second retracted configuration for enabling the first protrusions to position a first planar component

### BRIEF DESCRIPTION

For a better understanding of various examples of embodiments of the present invention reference will now be made by way of example only to the accompanying drawings in which:

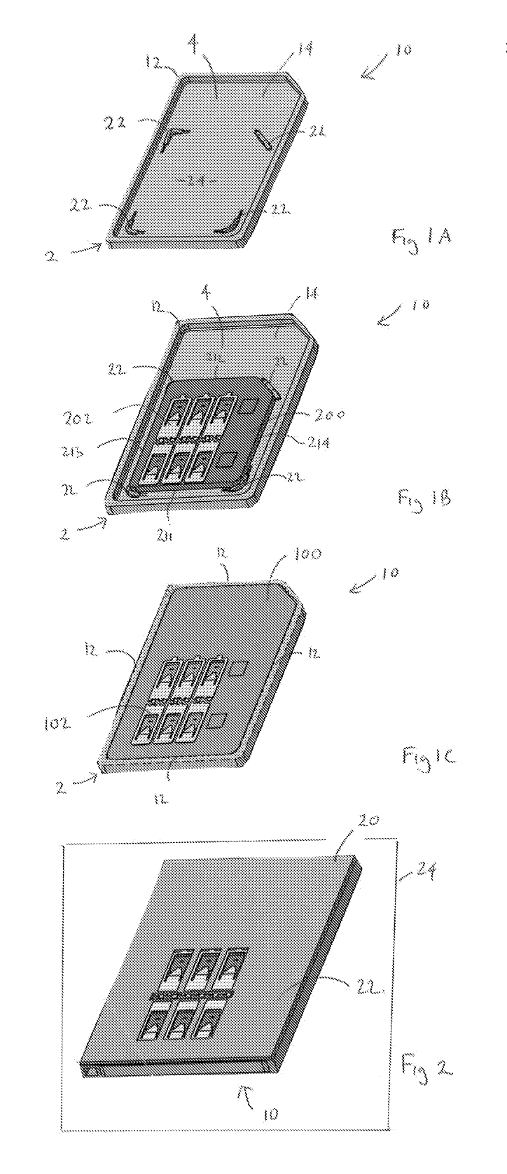

FIG. 1A illustrates an example of an apparatus without an inserted planar component;

FIG. 1B illustrates an example of an apparatus with an inserted smaller planar component;

FIG. 1C illustrates an example of an apparatus with an inserted larger planar component;

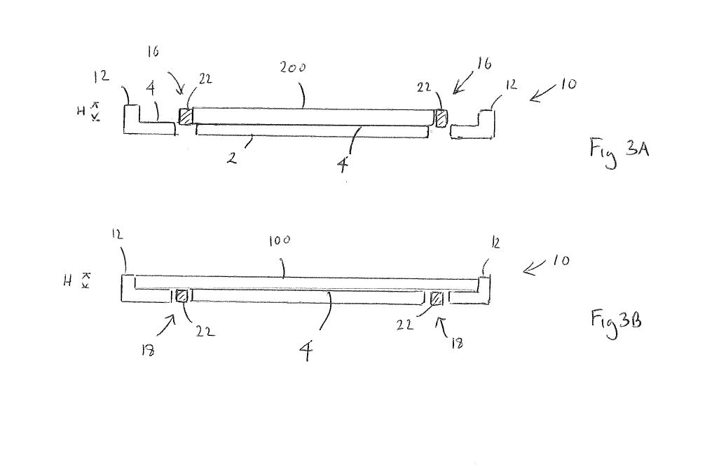

FIG. 2 illustrates an example of a receptacle housing an apparatus with an inserted planar component;

FIG. 3A illustrates a cross-section view of an example of an apparatus with an inserted smaller planar component, for example, as illustrated in FIG. 1B;

FIG. 3B illustrates a cross-section view of an example of an apparatus with an inserted larger planar component, for example, as illustrated in FIG. 1C;

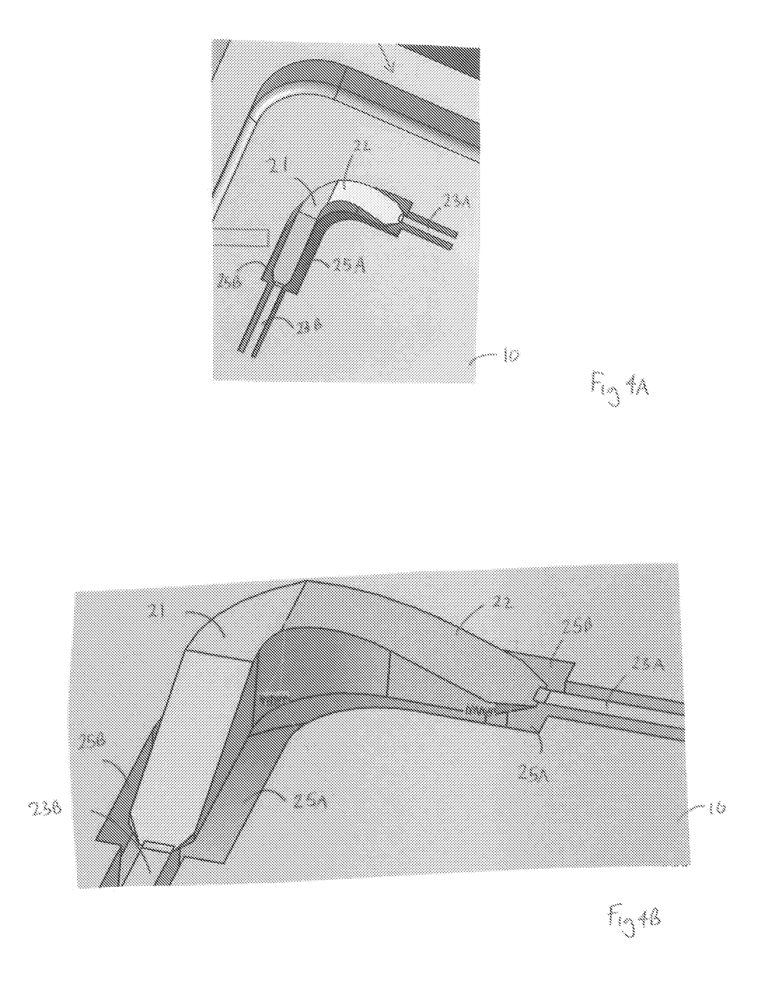

FIGS. 4A and 4B illustrate an example of a retractable protrusion for positioning and holding a smaller planar component;

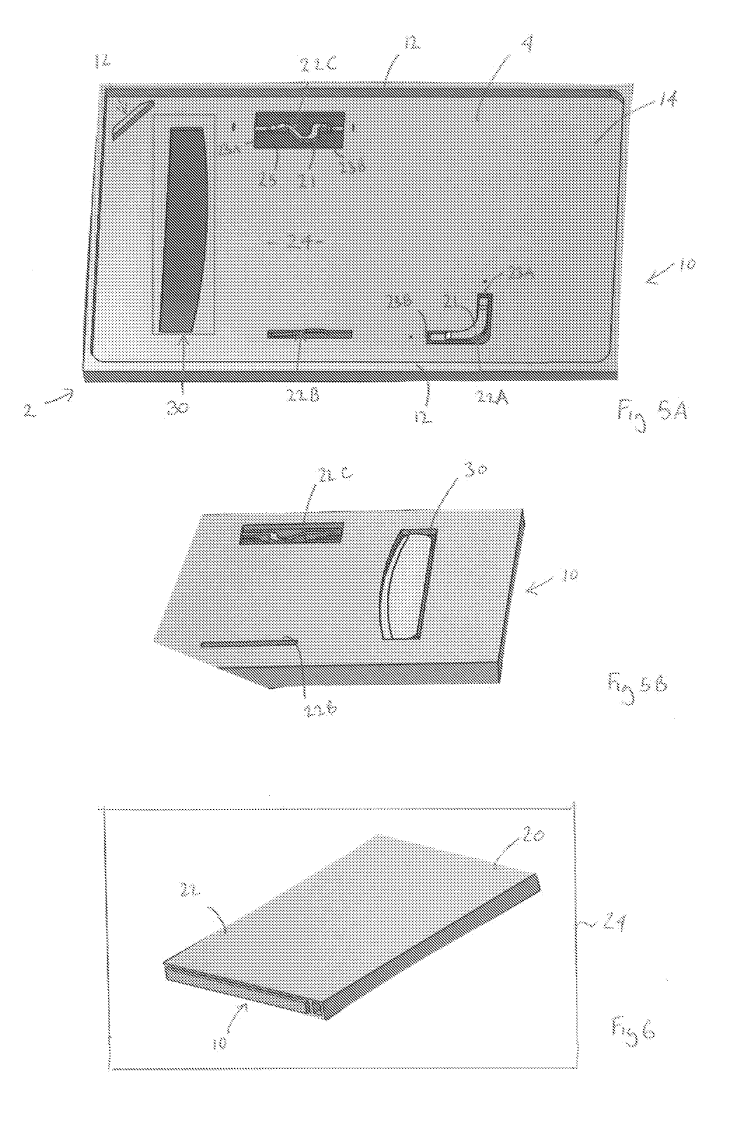

FIG. 5A illustrates another example of an apparatus without an inserted planar component;

FIG. 5B illustrates a rear view of the another example of the apparatus with an inserted planar component;

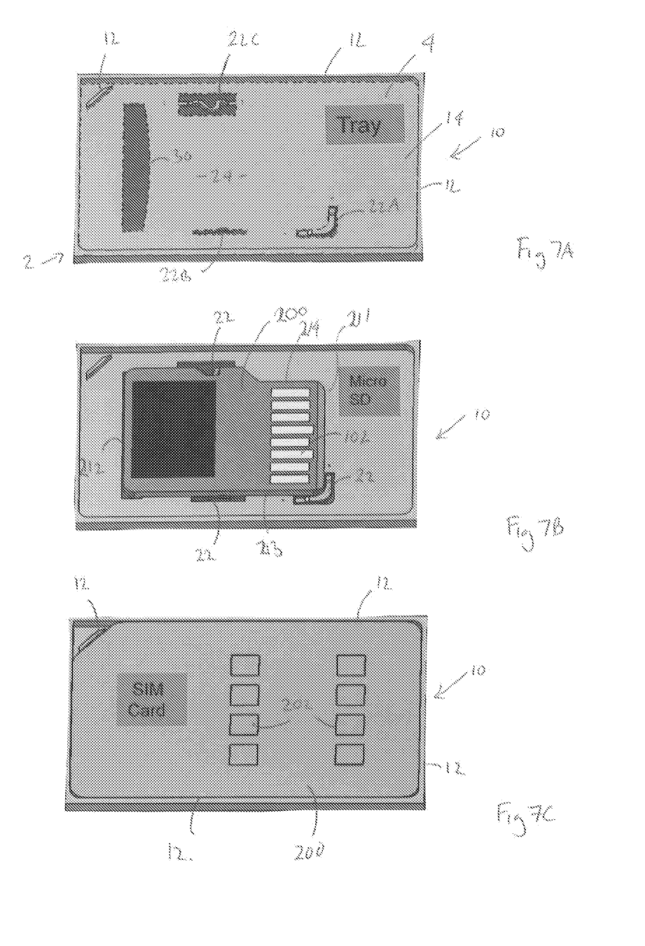

FIG. 6 illustrates an example of a receptacle housing an apparatus with an inserted planar component;

FIG. 7A illustrates an example of the apparatus of FIG. 5A without an inserted planar component;

FIG. 7B illustrates an example of the apparatus of FIG. 5A with an inserted smaller planar component; and

FIG. 7C illustrates an example of an apparatus of FIG. 5B with an inserted larger planar component.

### DETAILED DESCRIPTION

The Figures illustrate an apparatus 10 comprising: a support 2 comprising a planar support surface 4; first protrusions 12 protruding from the planar support surface 4 and located on the planar support surface 4 to position a first planar component 100 within a first area 14; and second protrusions 22 protruding from the planar support surface 4 and located on the planar support surface 4 to position a second planar component 200 within a second area 24, which overlaps the first area 14, wherein at least some of the second protrusions 22 are located within the first area 14 and are configured to retract from a first protruding configuration 16 for positioning a second planar component 200 into a second retracted configuration 18 for enabling the first protrusions 12 to position a first planar component 100.

FIG. 1A illustrates an example of an apparatus 10 without an inserted planar component. FIG. 1B illustrates an example of the apparatus 10 illustrated in FIG. 1A with an inserted second planar component 200 but not a first planar component 100. FIG. 1C illustrates an example of the apparatus illustrated in FIG. 1A with an inserted first planar component 100 but not a second planar component 200. FIG. 3A is a cross-sectional view through FIG. 1B. FIG. 3B is a cross-sectional view through FIG. 1C.

In this example, the second planar component 200 when received by the apparatus 10, is securely retained by frictional forces between retractable protrusions 22 of the apparatus 10 and edges 211, 212, 213, 214 of the second planar component 200.

In this example, the first planar component 100 when received by the apparatus 10, is securely retained by frictional forces between sidewall protrusions 12 of the apparatus 10 and edges of the first planar component 100 and the retractable protrusions 22 are retracted.

The first planar component 100 and the second planar component 200 are both user exchangeable. A user can insert either the first planar component 100 or the second planar component (but not both simultaneously) into the apparatus 10 without a tool. This is achieved by inserting a planar component from above by pushing it down into the apparatus 10 (rather than by sliding) towards a planar support surface 4 of a base support 2. A user can remove a planar component from the apparatus 10 without a tool.

In this example, the first planar component 100 and the second planar component 200 are differently sized. The first planar component 100 is larger than the second planar component 200.

The first planar component 100 may be a large card and the second planar component 200 may be a smaller card.

The first planar component 100 may be functionally similar to or functionally different to the second planar component 200.

Examples of possible planar components 100, 200 include but are not limited to: memory cards, smart cards, subscriber identity module (SIM) cards, user identity module (UIM) cards, etc.

For example, the first planar component 100 may be a standard SIM card (15 mm×25 mm), also known as a second form factor (2FF) smart card whereas the second planar component may be a micro SIM (12×15 mm), also known as a third form factor (3FF) smart card.

The apparatus 10, in the example of FIGS. 1A, 1B and 1C, is a tray that has a rigid base 2, fixed sidewalls 12 and retractable projections 22.

The base 2 is a support. It comprises a planar support surface 4.

When the first planar component 100 is received by the apparatus 10, most of a planar lower surface of the first planar component 100 rests on the planar support surface 4. A planar upper surface of the first planar component 100, comprising electrical contacts 102, is at a height H above the planar support surface 4. The sidewall protrusions 12 position the first planar component 100 such that the electrical contacts 102 are at first predetermined locations within a contact area.

When the second planar component 200 is received by the apparatus 10, most of a planar lower surface of the second planar component 200 rests on the planar support surface 4. A planar upper surface of the second planar component 200, comprising electrical contacts 202, is at the same height H above the planar support surface 4. The retractable protrusions 12 position the second planar component 200 such that the electrical contacts 202 are at second predetermined locations within the contact area. Some, all or none of the second predetermined locations may correspond to the first predetermined locations, in different designs of the apparatus 10.

The sidewalls 12 are fixed protrusions 12 that protrude upwards from the planar support surface 4. They are located on the planar support surface 4 with separations that position and secure a first planar component 100 within a first area 14, as illustrated in FIG. 1C.

The retractable protrusions 22 also protrude upwards from the same planar support surface 4 in FIG. 1A. They are located on the planar support surface 4 with mutual separations that position and secure a second planar component 200 within a second area 24, which overlaps the first area 14, as illustrated in FIG. 1B.

In this example, the second area 24 lies wholly within the first area 14 and all of the retractable protrusions 22 are located within the first area 14.

The retractable protrusions 22 are configured to retract from a first protruding configuration 16 (FIG. 1A, 1B, 3A) for positioning and securing a second planar component 200 into a second retracted configuration 18 (FIG. 1C, 3B). When the retractable protrusions 22 are in the second retracted configuration 18 they enable the sidewall protrusions 12 to position and secure a first planar component 100.

In this example, the second planar component 200 comprises a first edge 211 and a second edge 212 that form a first pair of parallel edges and a third edge 213 and a fourth edge 214 that form a second pair of parallel edges orthogonal to the first pair of parallel edges. The retractable protrusions 22 are located to grip each of the first edge 211, the second edge 212, the third edge 213 and the fourth edge 214 (FIG. 1B).

In this example, some of the retractable protrusions 22 are corner molds located and dimensioned to grip corners formed at the first edge 211 and the third edge 213, the first edge 211 and the fourth edge 214, and the second edge 212 and the third edge 213. Another of the protrusions is sized and located to grip a cut-off corner formed at the second edge 212 and the fourth edge 214. This non symmetric arrangement of retractable protrusions prevents incorrect insertion of the second planar component 200.

FIG. 2 illustrates an example of receptacle 20 housing an apparatus 10 with an inserted planar component. The apparatus 10 is received inside a receptacle 20. The receptacle 20 may be positioned inside an electronic device 24 as illustrated schematically in FIG. 2. The apparatus 10 may be slid into the receptacle 20 or rotated into the receptacle 20. The receptacle 20 comprises a cover portion 22 which overlies a planar component 100, 200 received by the apparatus 10. The cover portion may retain or help to retain or cover the planar component within the apparatus 10.

FIG. 3A illustrates the retractable protrusions 22 when they are in the first protruding configuration 16. The retractable protrusions extend upwards from the planar support surface 4 of the base support 2. The retractable protrusions 22 abut the edges of a second planar component 200 and position the second planar component within the apparatus 10. The retractable protrusions 22 may also grip the edges of the second planar component 200 and retain the second planar component within the apparatus 10.

FIG. 3B illustrates the retractable protrusions 22 when they are in the second retracted configuration 18. The retractable protrusions 22 have been retracted downwards into the base support 2 so that they are level with the planar support surface 4 of the supporting base 2. The sidewall protrusions 12 abut the edges of a first planar component 100 and position the first planar component 100 within the apparatus 10. The sidewall protrusions 12 may also grip the edges of a first planar component 100 and retain the first planar component 100 within the apparatus 10.

The retractable protrusions 22 are configured to be acted on directly by the first planar component 100 to change configuration from the first protruding configuration 16 to the second retracted configuration 18. The only moving parts are the retractable protrusions 22.

The retractable protrusions 22 are mounted for automatic retraction on user insertion of a first planar component 100. This retraction changes their configuration from the first configuration 16 to the second configuration 18.

The retractable protrusions 22 are mounted not to retract on user insertion of a second planar component 200.

The retractable protrusions 22 are resiliently mounted. In the first configuration 16 a resilient bias maintains the retractable protrusions 22 as protrusions above the planar support surface 4. On user insertion of a first planar component 100, the retractable protrusions 22 are forced downwards against the resilient bias until they are level with the planar support surface 4 (FIG. 3B). On user removal of the first planar component 100, the retractable protrusions 22 are forced upwards by the resilient bias until they are again protruding above the planar support surface 4 as illustrated in FIG. 3A.

FIGS. 4A and 4B illustrate an example of a retractable protrusion 22 with a resilient bias. In this example, the retractable protrusions are cantilevered lugs as illustrated in FIGS. 4A and 4B.

Each of the retractable protrusions 22 comprises a body 21 suspended between a first cantilever 23A and a second cantilever 23B.

Referring to FIG. 4A, the first cantilever 23A and the second cantilever 23B lie in the same plane as the planar support surface 4.

The body 21, the planar support surface 4 and the cantilevers 23A, 23B are formed from a single piece of plastics.

An aperture 25A through the planar support surface 4 defines an interior (innermost) edge of the first cantilever 23A, an interior edge of the body 21 and an interior edge of the second cantilever 23B.

An aperture 25B through the planar support surface 4 defines an exterior (outermost) edge of the first cantilever 23A, an exterior edge of the body 21 and an exterior edge of the second cantilever 23B.

When the retractable protrusion 22 is in the first protruding configuration 16, the cantilevers 23A, 23B are in equilibrium and maintain the first protruding configuration 16.

When the retractable protrusion 22 is in the second retracted configuration 18, the cantilevers 23A, 23B are bent downwards such that an upper portion is under tension and a lower portion is under compression. The rigidity of the cantilevers 23A, 23B biases them to return the body 21 of the retractable protrusion 22 to the first protruding configuration 16.

FIG. 5A illustrates another example of an apparatus without an inserted planar component. FIG. 7A illustrates an example of the apparatus 10 of FIG. 5A without an inserted planar component. FIG. 7B illustrates the apparatus 10 of FIG. 5A with an inserted second planar component 200. FIG. 7C illustrates the apparatus 10 of FIG. 5B with an inserted first planar component 100.

FIGS. 7A, 7B and 7C are similar to FIGS. 1A, 1B and 1C. The apparatuses 10 are similar but not identical and similar references are used to denote similar features. The planar components are similar but not identical and similar references are used to denote similar features.

The apparatus 10 illustrated in FIGS. 7A, 7B and 7C operates similarly to the apparatus 10 illustrated in FIGS. 1A, 1B and 1C and the description given with reference to FIGS. 1A, 1B and 1C is also applicable to FIGS. 7A, 7B and 7C except as detailed below.

The apparatus 10 illustrated in FIG. 5 and FIGS. 7A to 7C has an aperture 30 through the base support 2. This aperture 30 exposes a lower surface of a planar component 100, 200 received by the apparatus 10. The aperture 30 is sized to receive a finger tip. It aids user removal of the planar component. A user can push the planar component out of the apparatus 10 through the aperture 30 using their finger tip. FIG. 5B illustrates a rear view of the apparatus 10 with an inserted planar component visible through the aperture 30.

The apparatus 10 illustrated in FIGS. 5 and 7A-7C has an alternative arrangement of retractable protrusions 22 compared to the apparatus 10 illustrated in FIGS. 1A to 1C. However, they still operate to position and retain a second planar component 200 and are retractable to enable positioning of a first planar component 100 by the sidewall protrusions 12.

As previously described, the second planar component 200 comprises a first edge 211 and a second edge 212 that form a first pair of parallel edges and a third edge 213 and a fourth edge 214 that form a second pair of parallel edges orthogonal to first pair of parallel edges.

The retractable protrusions 22 are located to abut each of the first edge 211, the third edge 213, and the fourth edge 214. The retractable protrusions 22 may also grip each of each of the first edge 211, the third edge 213, and the fourth edge 214. The retractable protrusions 22 are separately labelled 22A, 22B, 22C in FIGS. 5A and 7A to 7C.

The retractable protrusion 22A is similar to the retractable protrusions 22 previously described with reference to FIG. 1B and FIGS. 4A and 4B. It is cantilevered and is a corner mold located to grip a corner formed at the first edge 211 and the third edge 213 of the second planar component 200 (as in FIGS. 4A and 4B).

The retractable protrusion 22B is different to the retractable protrusions 22 previously described in relation to FIG. 1B. It also is cantilevered to retract into the planar support surface 4 but is located to grip only the third edge 213 of the second planar component 200. The retractable protrusion 22B has similar components to the retractable protrusion 22 illustrated in FIGS. 4A and 4B except that it is shaped to grip only an edge rather than a corner.

The retractable protrusion 22C is different to the retractable protrusions previously described in relation to FIG. 1B. It is also cantilevered to retract into the planar support surface 4 but is located to grip only the fourth edge 214 of the second planar component 200. The retractable protrusion 22C has similar components to the retractable protrusion 22 illustrated in FIGS. 4A and 4B except that it is shaped to grip only an edge rather than a corner. In this example, the fourth edge 214 comprises a notch and the retractable protrusion 22C has a correspondingly shaped mating body 21 that is received by the notch. The notch creates asymmetry which prevents incorrect insertion of the second planar component 200.

The retractable protrusion 22C is configured to be resiliently forced laterally outwards from the second area 24 by an edge 214 of a second planar component 200 on user insertion of the second planar component and to resiliently return to grip the edge 214 of the second planar component 200.

FIG. 6 illustrates an example of receptacle 20 housing an apparatus 10 with an inserted planar component. The apparatus 10 is received inside a receptacle 20. The receptacle 20 may be positioned inside an electronic device 24 as illustrated schematically in FIG. 6. The apparatus 10 may be slid into the receptacle 20 or rotated into the receptacle 20. The receptacle 20 comprises a cover portion 22 which overlies a planar component received by the apparatus 10. The cover portion may retain or help to retain or cover the planar component within the apparatus 10.

As used here ‘module’ refers to a unit or apparatus that excludes certain parts/components that would be added by an end manufacturer or a user. The apparatus 10 may be a module. The planar components 100, 200 may be modules.

It will be appreciated from the foregoing that some embodiments of the present invention may provide a method comprising:

providing first protrusions 12 protruding from a planar support surface 4 and located on the planar support surface 4 to position a first planar component 100 within a first area 14; and

providing second protrusions 22 protruding from the planar support surface 4 and located on the planar support surface 4 to position a second smaller planar component 200 within a second area 24, which overlaps the first area 14, wherein at least some of the second protrusions 22 are located within the first area 14 and are configured to retract from a first protruding configuration 16 for positioning a second planar component 100 into a second retracted configuration 18 for enabling the first protrusions 22 to position a first planar component 100.

One or more of the retractable protrusions 22, 22A, 22B, 22C may also be configured as a detector that detects when a second planar component 200 has been inserted into the apparatus 10. The detector may be configured to provide a detection signal to a host apparatus housing the apparatus 10. The host apparatus may comprise a memory and a processor and software in the memory may be run on the processor to interpret the detection signal as insertion of a second planar component 200. As an example, the switch 22B of the apparatus 20 illustrated in FIG. 7A may be configured as a detector.

Although embodiments of the present invention have been described in the preceding paragraphs with reference to various examples, it should be appreciated that modifications to the examples given can be made without departing from the scope of the invention as claimed.

Features described in the preceding description may be used in combinations other than the combinations explicitly described.

Although functions have been described with reference to certain features, those functions may be performable by other features whether described or not.

Although features have been described with reference to certain embodiments, those features may also be present in other embodiments whether described or not.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

1-24. (canceled)

25. An apparatus comprising:
a support comprising a planar support surface;
first protrusions protruding from the planar support surface and located on the planar support surface to position a first planar component within a first area; and
second protrusions protruding from the planar support surface and located on the planar support surface to position a second planar component within a second area, which overlaps the first area,
wherein at least some of the second protrusions are located within the first area and are configured to retract from a first protruding configuration for positioning a second planar component into a second retracted configuration for enabling the first protrusions to position a first planar component.

26. An apparatus as claimed in claim 25, wherein the second protrusions are configured to retract into the planar support surface in the second configuration.

27. An apparatus as claimed in claim 25, wherein the second protrusions are configured for automatic retraction on user insertion of a first planar component from the first configuration to the second configuration and are configured not to retract on user insertion of a second planar component.

28. An apparatus as claimed in claim 25, wherein the second protrusions are configured to be resiliently forced into the planar support surface on user insertion of a first planar component.

29. An apparatus as claimed in claim 25, wherein the second protrusions are configured to be acted on directly by a first planar component to change configurations from the first protruding configuration to the second retracted configuration.

30. An apparatus as claimed in claim 25, wherein the second protrusions are cantilevered lugs.

31. An apparatus as claimed in claim 25, wherein at least one of the second protrusions comprises a body suspended between a first cantilever and a second cantilever.

32. An apparatus as claimed in claim 31, wherein the first cantilever and the second cantilever lie in the same plane as the planar support surface.

33. An apparatus as claimed in claim 31, wherein the body, the first and second cantilevers and the planar support surface are formed from a single piece of plastics.

34. An apparatus as claimed in claim 25, wherein the planar support comprises an aperture.

35. An apparatus as claimed in claim 25, wherein the second planar component comprises a first edge and a second edge that form a first pair of parallel edges and a third edge and a fourth edge that form a second pair of parallel edges orthogonal to the first pair of parallel edges, wherein the second protrusions are located to grip each of the first edge, the third edge and the fourth edge.

36. An apparatus as claimed in claim 25, wherein the second planar component comprises a first edge and a second edge that form a first pair of parallel edges and a third edge and a fourth edge that form a second pair of parallel edges orthogonal to that first pair of parallel edges, wherein the second protrusions are located to grip each of each of the first edge, the second edge, the third edge and the fourth edge.

37. An apparatus as claimed in claim 35, wherein the second protrusions are located to grip corners formed at the first edge and the third edge, the first edge and the fourth edge, and the second edge and the third edge.

38. An apparatus as claimed in claim 37, wherein at least one of the second protrusions is sized and located to grip a cut-off corner formed at the second edge and the fourth edge.

39. An apparatus as claimed in claim 35, wherein the second protrusions are located to grip a corner formed at the first edge and the third edge.

40. An apparatus as claimed in claim 39, wherein at least one of the second protrusions is located to grip only the fourth edge.

41. An apparatus as claimed in claim 25, wherein at least one of the second protrusions is configured to be resiliently forced laterally outwards from the second area by an edge of a second planar component on user insertion of the second planar component and to resiliently return to grip the edge of the second planar component.

42. An apparatus as claimed in claim 41 wherein the edge where gripped by the second protrusion is notched.

43. An electronic device comprising the apparatus as claimed in claim 25.

44. A method comprising:
providing first protrusions protruding from a planar support surface and located on the planar support surface to position a first planar component within a first area; and
providing second protrusions protruding from the planar support surface and located on the planar support surface to position a second smaller planar component within a second area, which overlaps the first area, wherein at least some of the second protrusions are located within the first area and are configured to retract from a first protruding configuration for positioning a second planar component into a second retracted configuration for enabling the first protrusions to position a first planar component.
